(19) United States
(12) Patent Application Publication
(10) Pub. No.: US 2010/0301883 A1
(43) Pub. Date: Dec. 2, 2010

(54) Method and Apparatus for Detecting a Fault in a Neutral Return Line of an Electrical Network

(76) Inventors: Erickson Bruce Meyers, Tasmania (AU); Bryan Douglas Holter, Tasmania (AU)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/808,143

(22) PCT Filed: Sep. 17, 2008
(86) PCT No.: PCT/AU08/01372

§ 371 Date: Jul. 13, 2010

(30) Foreign Application Priority Data
Dec. 19, 2007 (AU) 2007906977

(51) Int. Cl. G01R 27/08; G08B 21/00

(52) U.S. Cl. 324/705; 340/660

(57) ABSTRACT

Apparatus is disclosed for detecting a discontinuity or irregularity in a neutral return line of an electrical power distribution network including the neutral return line, an active line and an earth return. The apparatus includes means for measuring a voltage change associated with a deliberate switching of a known impedance in the electrical network wherein the voltage change is due to a discontinuity or impedance irregularity in the neutral return line and means for implementing an algorithm for identifying the discontinuity or impedance irregularity in presence of allowable variations in nominal supply voltage to the electrical network including voltage changes resulting from network operations that mimic or hide a discontinuity or impedance irregularity in the neutral return line. The apparatus also includes means for comparing a result of the measuring with a reference to provide an indication of the discontinuity or impedance irregularity. A method for detecting a discontinuity or irregularity in a neutral return line of an electrical power distribution network is also disclosed.

### BACKGROUND OF INVENTION

The present invention relates to monitoring and/or detecting faults in supply lines of an electrical power distribution network. In particular the invention relates to detecting a fault such as a discontinuity or impedance irregularity in a supply line of an electrical network where a voltage potential may be present resulting in a danger of electric shock to persons with a possibility of injury or death.

The electricity power supply industry generally has an earthed return system to provide a protected path in the case of faults. Flow of current in the system is normally between active and neutral return. The system allows current to flow between active and earth return when a fault occurs in equipment connected to the system.

Because current can flow in one of two circuits (neutral or earth), a discontinuity or impedance irregularity in one circuit can go undetected for a period of time without any indication of danger until the second circuit (neutral or earth) also becomes defective.

For example, a high impedance or discontinuity in a neutral line or wire may allow current to flow between active and earth. However, the earth return path may become ineffective or defective over time due to a number of factors including drying out of the soil, a faulty connection or cable damage following work carried out on plumbing or the like. When a sound earth return path is not in place current may flow to earth through other paths such as water pipes and storm drains or it may not flow at all. The latter may cause a rise in voltage potential above earth and create a danger of electric shock to persons with a possibility of injury or death.

An object of the present invention is to at least alleviate the disadvantages of the status quo.

### SUMMARY OF THE INVENTION

According to one aspect of the present invention there is provided an apparatus for detecting a discontinuity or irregularity in a neutral return line of an electrical power distribution network including said neutral return line, an active line and an earth return, said apparatus including:

means for measuring a voltage change associated with a deliberate switching of a known impedance in said electrical network wherein said voltage change is due to a discontinuity or impedance irregularity in said neutral return line;
means for implementing an algorithm for identifying said discontinuity or impedance irregularity in presence of allowable variations in nominal supply voltage to said electrical network including voltage changes resulting from network operations that mimic or hide a discontinuity or impedance irregularity in said neutral return line; and
means for comparing a result of said measuring with a reference to provide an indication of said discontinuity or impedance irregularity.

The algorithm may be implemented to discriminate a network that includes the neutral return line from a network that does not include the neutral return line in presence of anomalies in the supply voltage. The reference may be selected to discriminate a network that includes the neutral return line from a network that does not include the neutral return line. The reference may include data samples obtained from a plurality of sites when the network does not include the neutral return line. The reference may include data samples obtained from a plurality of sites when the network does include the neutral return line.

The apparatus may include means for measuring the voltage change in the network including voltage change that results from random or natural switching of impedances in the network. The apparatus may include means for measuring the voltage change in the network including voltage change that results from the deliberate switching of a known impedance in the network. The means for measuring may include an analog to digital converter. The means for comparing may include a microprocessor and a memory for storing data associated with the reference. The indication may include an audible and/or visual alarm and/or an electrical signal.

According to a further aspect of the present invention there is provided a method for detecting a discontinuity or irregularity in a neutral return line of an electrical power distribution network including said neutral return line, an active line and an earth return, said method including:

measuring a voltage change associated with a deliberate switching of a known impedance in said electrical network wherein said voltage change is due to a discontinuity or impedance irregularity in said neutral return line;
implementing an algorithm for identifying said discontinuity or impedance irregularity in presence of allowable variations in nominal supply voltage to said electrical network including voltage changes resulting from network operations that mimic or hide a discontinuity or impedance irregularity in said neutral return line; and
comparing a result of said measuring with a reference to provide an indication of said discontinuity or impedance irregularity.

The present invention may detect a discontinuity or impedance irregularity in a neutral return line or wire or earth return path. The present invention may detect the discontinuity or irregularity at a consumer site. The present invention may detect the discontinuity or irregularity by monitoring and/or measuring a voltage change or drop in an electrical circuit associated with the network. The voltage change or drop may be associated with a deliberate switching of a known impedance in the electrical circuit. The voltage change or drop may be caused by a discontinuity and/or impedance irregularity in the neutral return line. The present invention may include an algorithm which can identify a discontinuity or impedance irregularity in the neutral return line. The algorithm may distinguish allowable variations in “nominal supply voltage” as well as voltage changes including steps, sags, spikes, etc. attributable to normal network operations that may either mimic or hide a discontinuity or impedance irregularity in the neutral return line.

Electrical properties as well as physical dimensions and characteristics of electrical circuits that develop a discontinuity or irregularity in a neutral line or wire may differ from those present in electrical circuits that retain an intact neutral line or wire.

Given a stable supply voltage, an expected voltage change or drop in a circuit may depend upon series and parallel impedances in the circuit, impedance of the neutral wire return, and impedance of an earth return path. Under a condition of a discontinuity or impedance irregularity in the neutral wire, the expected voltage change or drop may depend primarily on the value of the earth return path impedance and will generally be measurably greater than in an intact neutral case.

Measurement of a change or drop in line voltage resulting from a change in impedance in a network may be used to indicate a discontinuity or impedance irregularity in a supply line of an electrical power distribution network. Measurable voltage changes or drops may result from naturally occurring random switching of impedances within an electrical network, or may result from deliberate or planned switching of impedance in an electrical network.

As the impedance of a neutral return line or wire is generally less than that of an earth return path, presence of a voltage potential under conditions of high earth return impedance may result in a danger of electric shock to persons with a possibility of injury or death. The latter situation may be detected by comparing a voltage change or drop for a given impedance to a reference. The reference may represent a voltage change or drop that would be expected when the neutral return line is intact or unbroken, or when the neutral return line is unbroken but has an impedance irregularity.

The present invention includes apparatus for detecting a discontinuity or irregularity in a supply line of an electrical power distribution network. The discontinuity or irregularity may be present anywhere between a supply transformer and a point of connection of the apparatus to the power distribution network. The apparatus may be installed as a separate apparatus in a customer's premises at a convenient location such as a General Purpose Outlet (GPO) or switchboard or it may be associated or integrated with the GPO or metering equipment installed for the customer by an electricity service provider.

The apparatus may be adapted to differentiate between circuits having an intact neutral return line, and circuits having a discontinuity or irregularity in a neutral return line. The apparatus may measure a change or drop in a line voltage resulting from a change in impedance within an electrical network. The change or drop in voltage may be used to indicate a change in impedance of an electrical return path in the electrical network. The measured voltage changes or drops may result from random switching of impedances produced within the electrical network, or may result from deliberate or planned switching of impedance by the apparatus in an associated circuit.

Electricity distribution supply networks generally provide electricity at a defined “nominal supply voltage” that may vary between allowable high and low bounds. In addition to these allowable variations in “nominal supply voltage” are voltage changes, (steps, sags, spikes, etc.) resulting from normal network operations. These include voltage rises or drops due to various factors including loads imposed on the local or distribution network, overloading of transformers, switching, lightning strikes, re-closer operation, etc.

As naturally occurring voltage sags and spikes in a supply voltage can result in voltage drops or rises that may mimic or hide a discontinuity or impedance irregularity in a neutral supply line, the apparatus may include an algorithm that may minimise impact of such anomalous events on reliable detection of the discontinuity or impedance irregularity in the neutral supply line. Thus the algorithm may allow for identification of a discontinuity or impedance irregularity in a neutral supply line under anomalous voltage conditions.

The apparatus may include means such as an audible or visual signal or an alarm to communicate to the consumer and/or a third party that a neutral return line or wire may contain a discontinuity or irregularity.

Preferred embodiments of the present invention will now be described with reference to the accompanying drawings wherein;

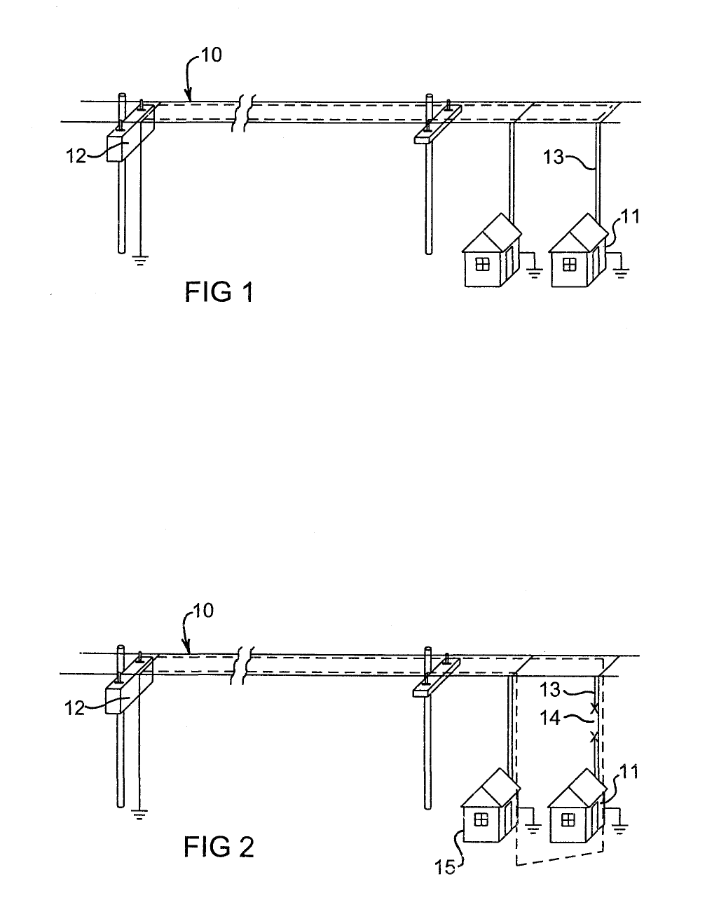

FIG. 1 shows a simplified diagram of a typical intact installation;

FIG. 2 shows a simplified diagram of a faulty installation;

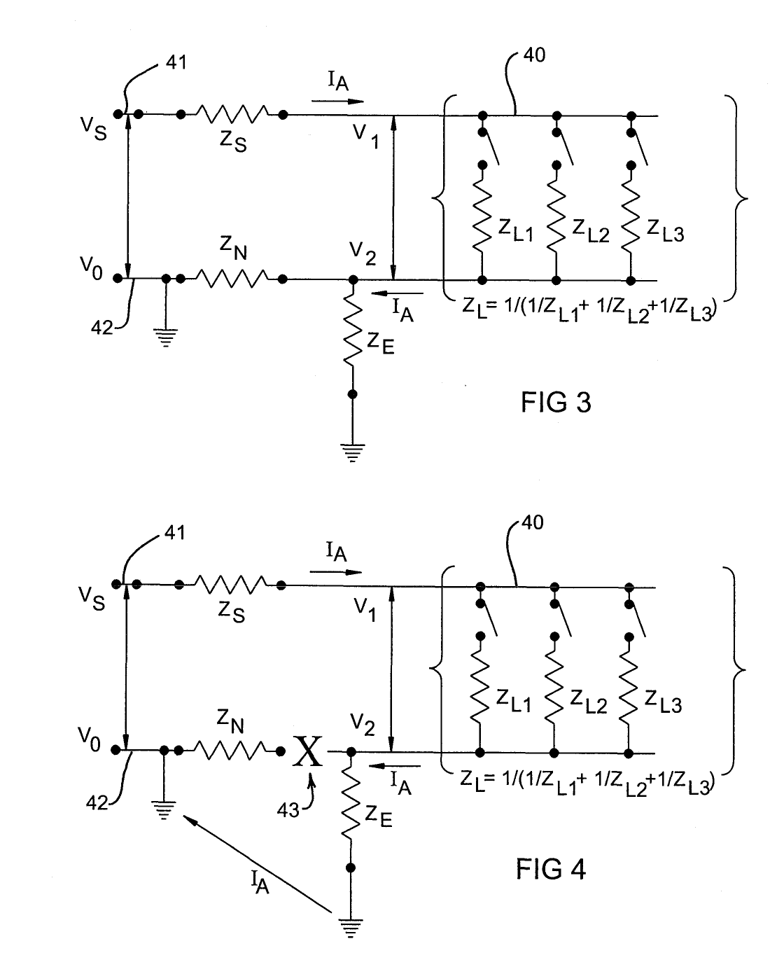

FIG. 3 shows a representation of a local network including an intact neutral return line;

FIG. 4 shows a representation of a local network including a discontinuous neutral return line;

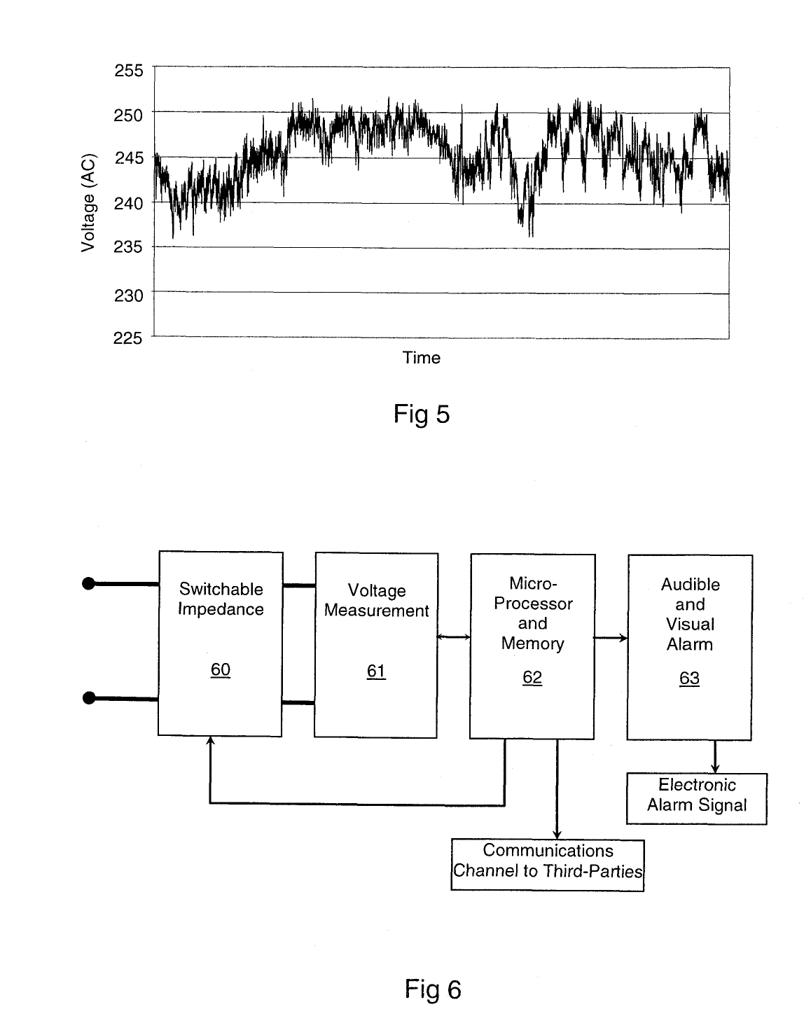

FIG. 5 shows a representation of normal variations in “nominal voltage” including randomly occurring voltage sags and spikes;

FIG. 6 shows a block diagram of an apparatus for detecting a discontinuity in an electrical power distribution system;

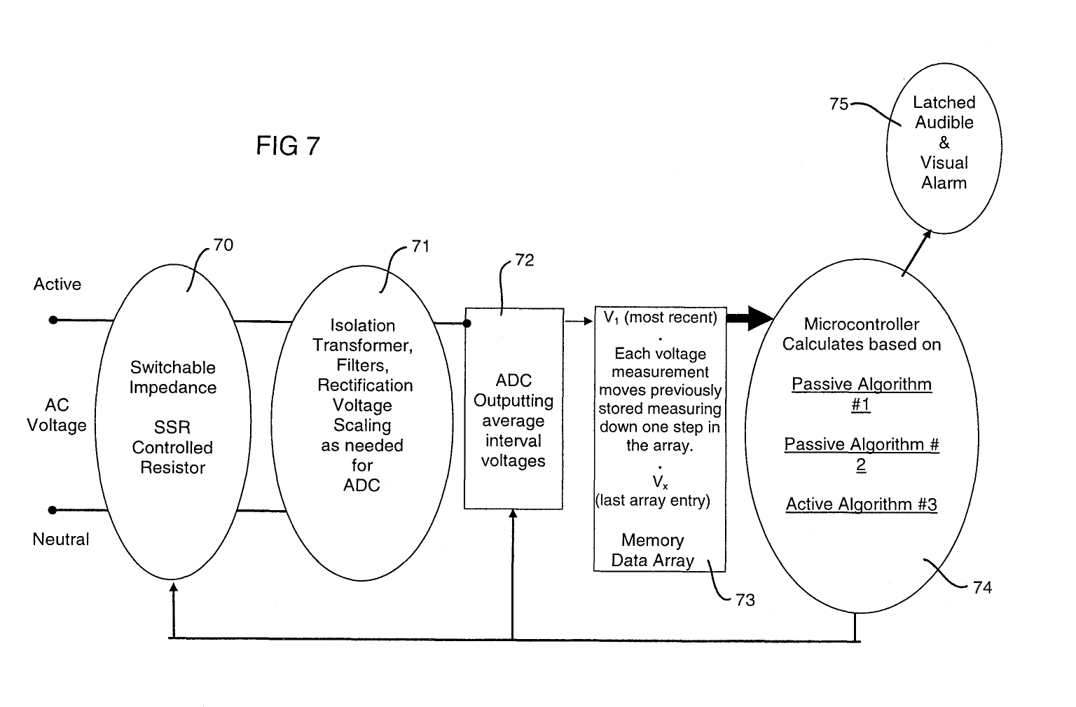

FIG. 7 shows a block diagram of one form of apparatus according to the present invention;

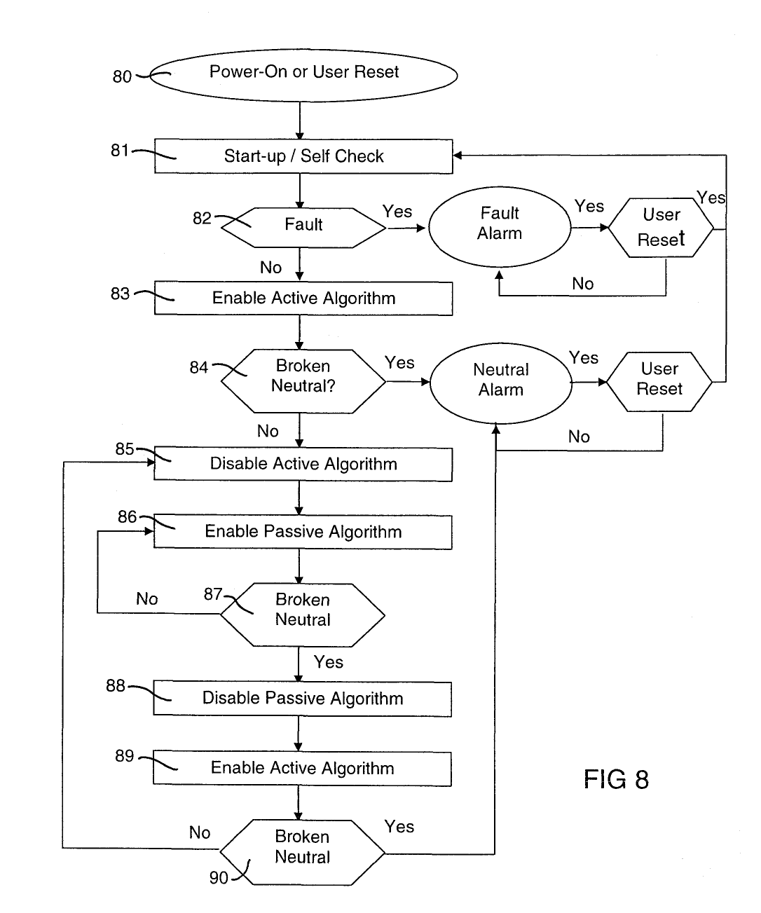

FIG. 8 shows a flow diagram of one form of active voltage test and passive voltage test;

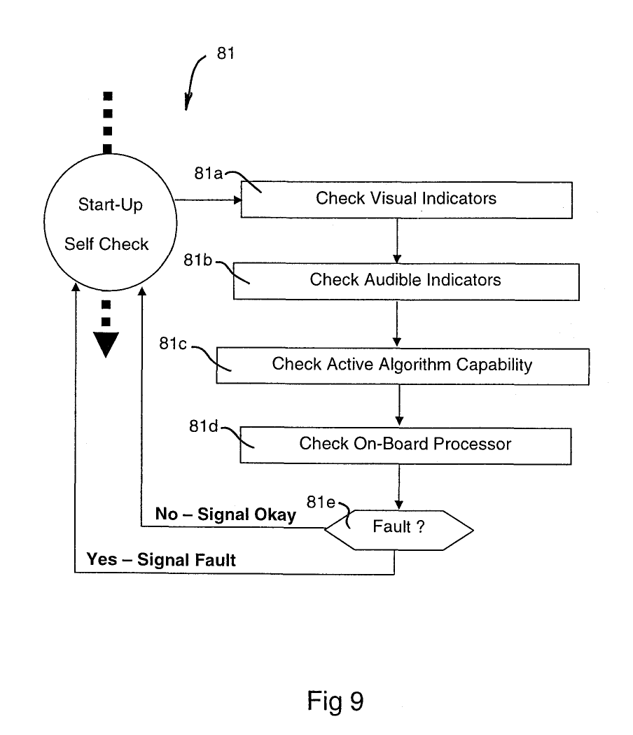

FIG. 9 shows a sub-process for a self check;

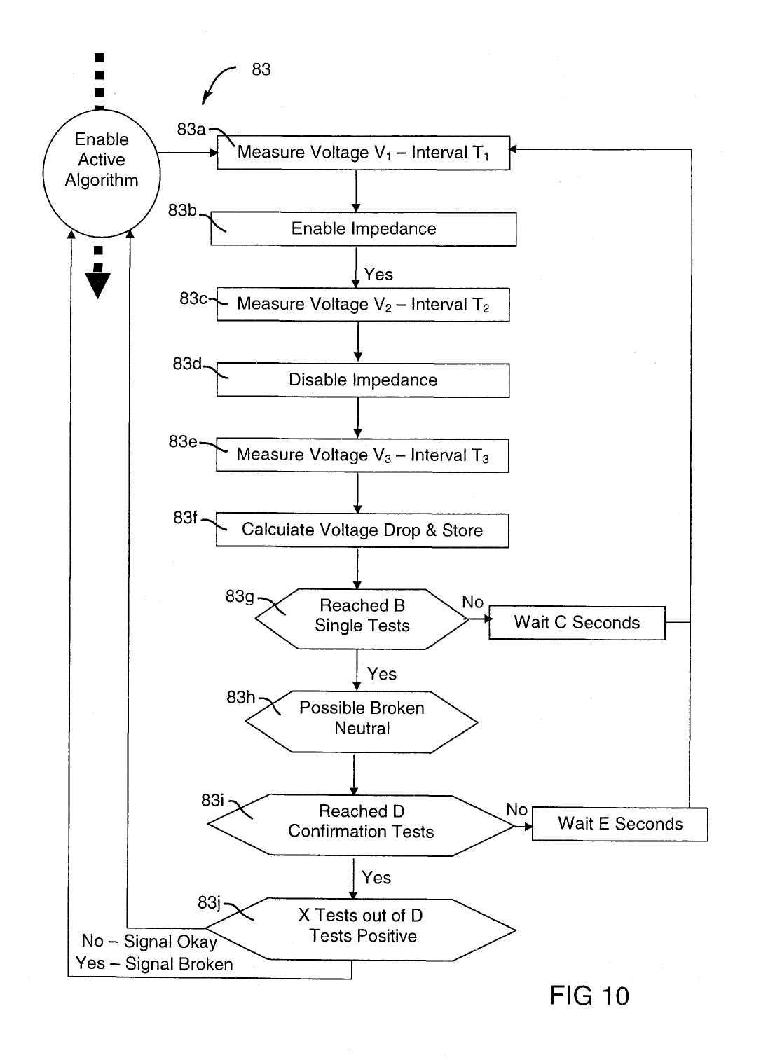

FIG. 10 shows a sub-process for an active voltage test;

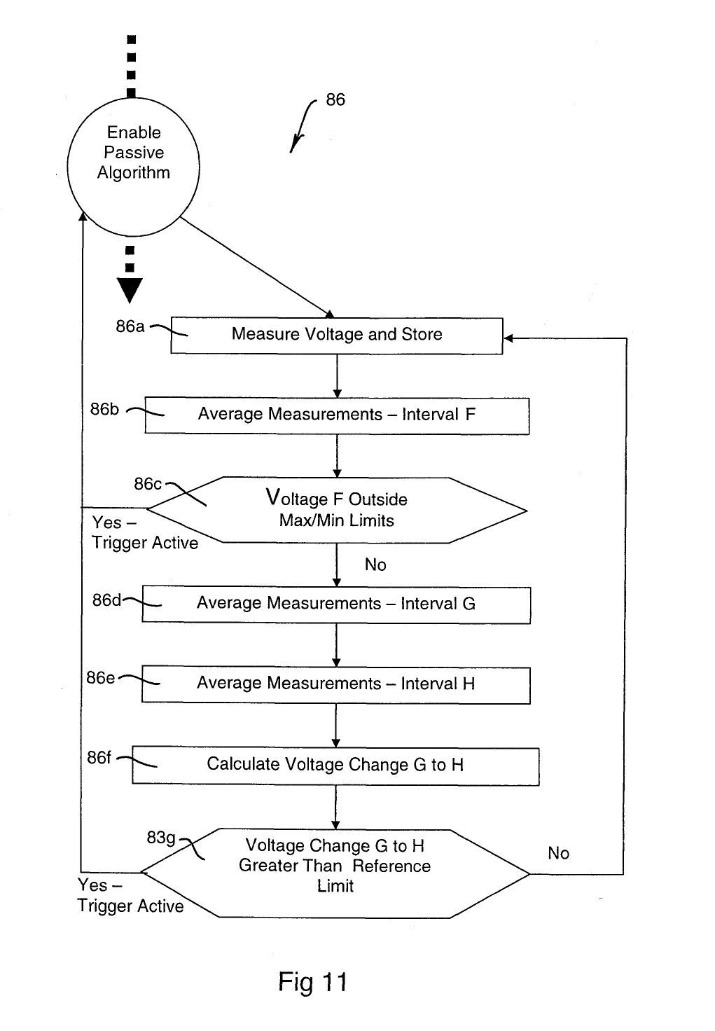

FIG. 11 shows a sub-process for a passive voltage test;

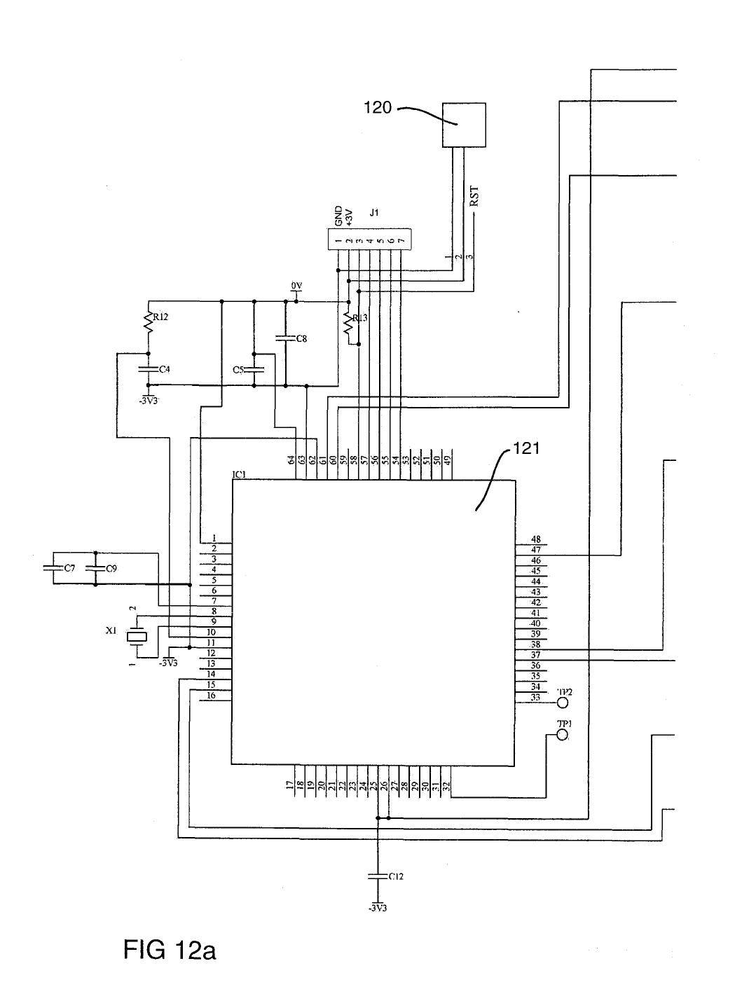

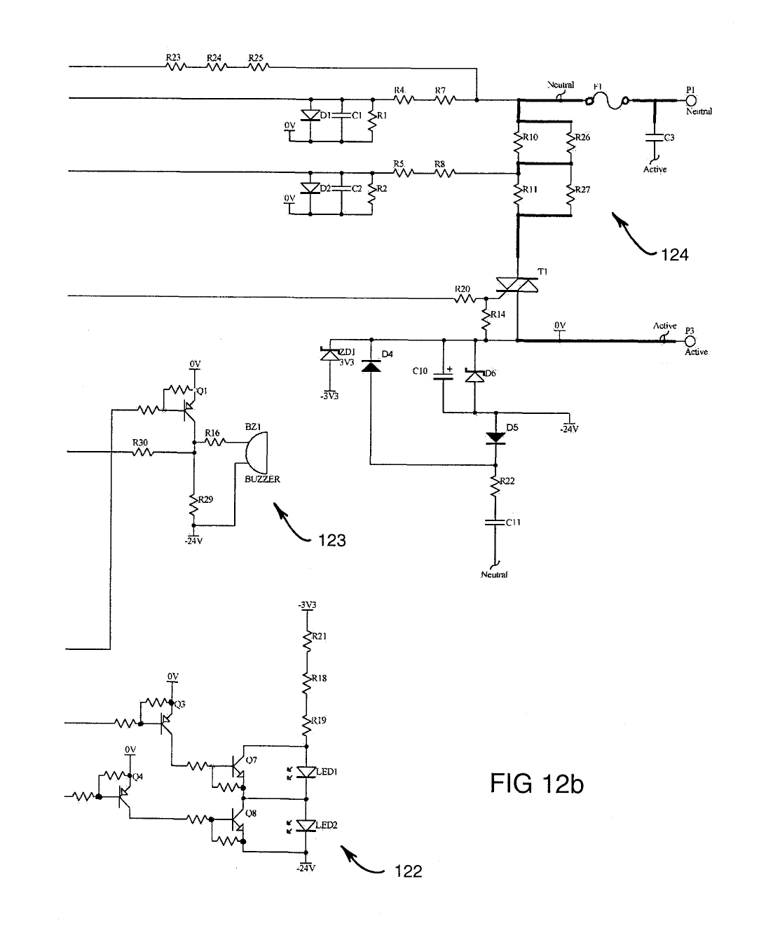

FIGS. 12a and 12b show a schematic diagram of one form of apparatus according to the present invention;

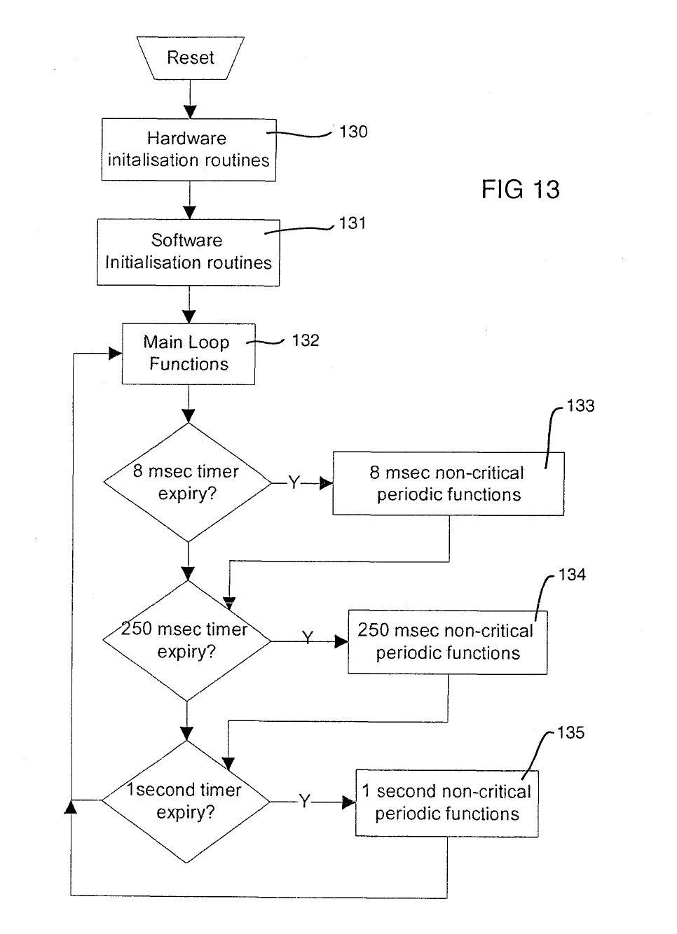

FIG. 13 shows a flow diagram of an algorithm for main system control;

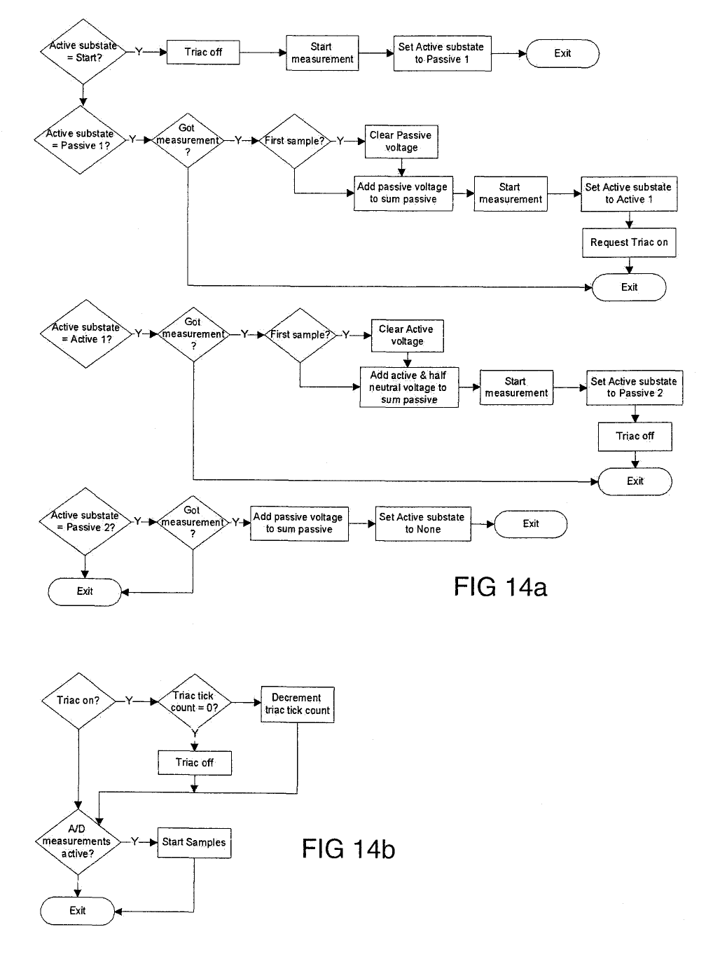

FIG. 14a shows a flow diagram of an algorithm for 8 mS non-critical functions;

FIG. 14b shows a flow diagram of an algorithm for 250 mS non-critical functions;

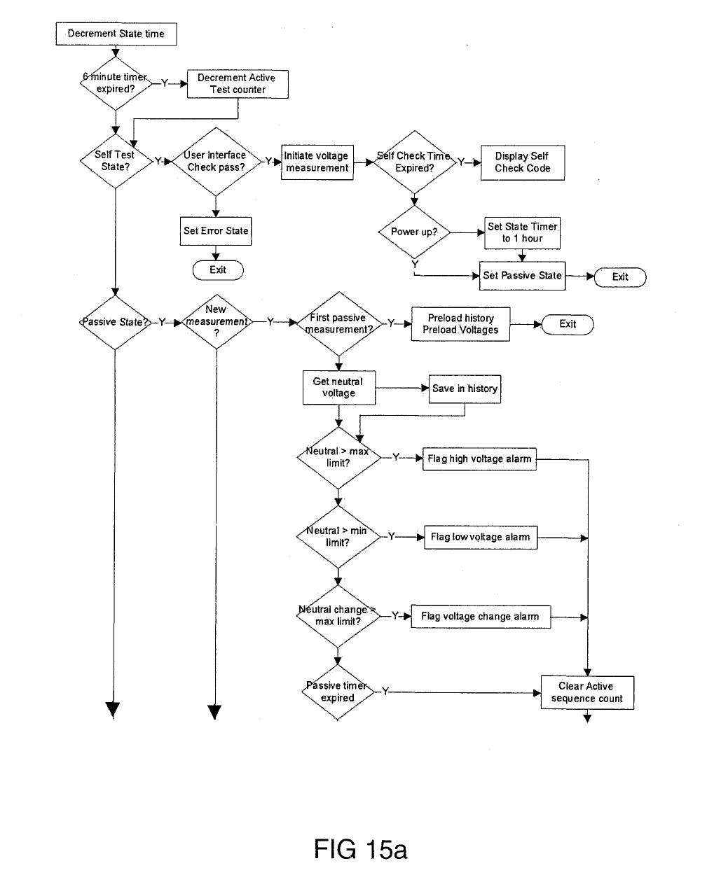

FIG. 15a shows a flow diagram of a first half of an algorithm for 1 second non-critical functions;

FIG. 15b shows a flow diagram of a second half of the algorithm for 1 second non-critical functions;

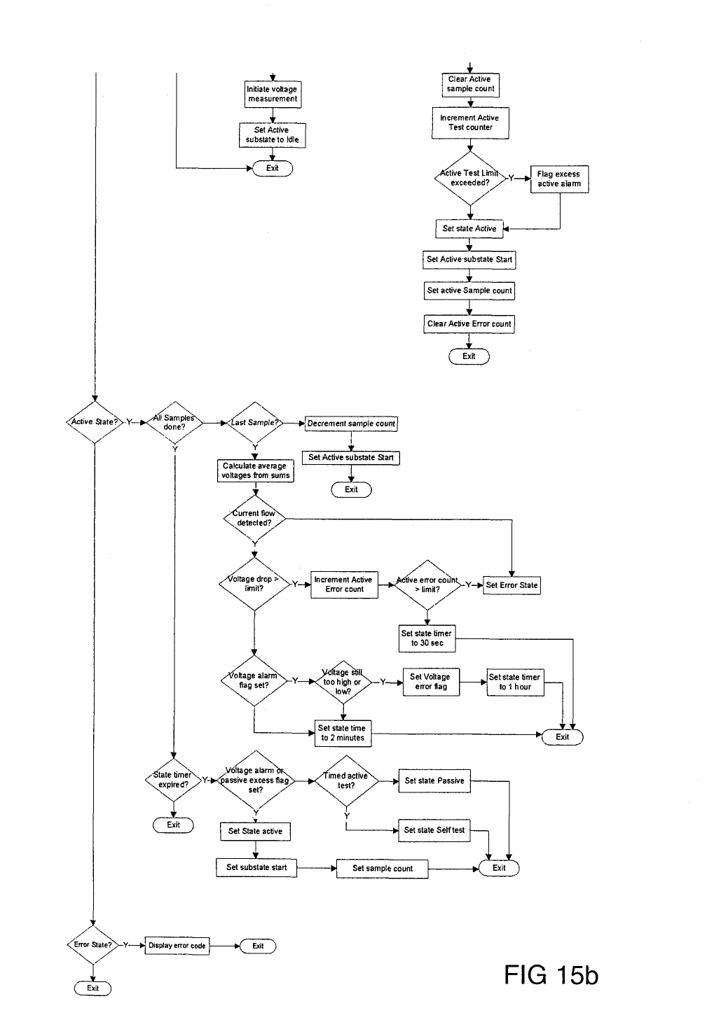

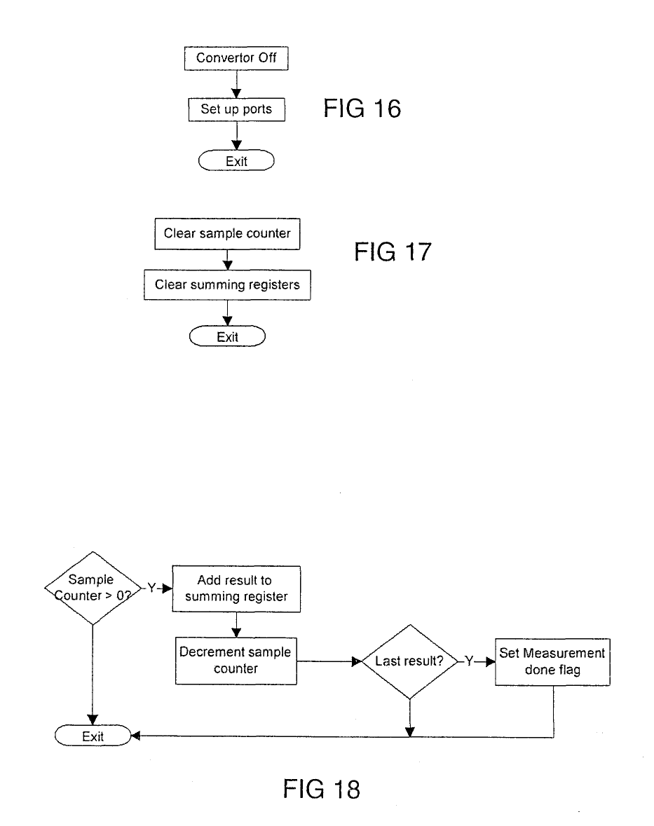

FIG. 16 shows a flow diagram of an algorithm for hardware initialisation in an A/D converter module;

FIG. 17 shows a flow diagram of an algorithm for software initialisation in the A/D converter module; and

FIG. 18 shows a flow diagram of functions following completion of an analogue to digital conversion.

FIG. 1 shows a simplified example of a domestic electrical power supply installation including overhead transmission line 10 between house 11 and distribution transformer 12. The installation has an intact neutral return line 13 between house 11 and distribution transformer 12.

FIG. 2 shows the same domestic power supply installation including a break 14 in the neutral return line 13 to house 11. In this case the earth and the water-pipe bond form a secondary connection with the neutral connection of house 15 next door and/or with an earth return connection of distribution transformer 12.

FIG. 3 shows a representation of a local network 40 including a plurality of naturally switched loads Z_{L1}, Z_{L2}, Z_{L3} connected between active line 41 and neutral line 42. A local current I_{A} flows between the active and neutral lines determined by voltage V₁ across the local network and total local network impedance. Assuming that the neutral line 42 is intact the voltage V₁ measured across the local network equals the active supply voltage Vₛ. The impedance Zₛ represents the source impedance associated with active line 41, impedance Z_{N} represents the impedance associated with neutral line 42, while local earth impedance is represented by Z_{E}. Local current I_{A} will flow through impedances Z_{N} and Z_{E} based upon their relative impedances so long as both the neutral return line, and earth return remain intact. The difference between impedances Z_{N} and Z_{E} is generally such that it results in preferential current flowing through impedance Z_{N}.

FIG. 4 shows local network 40 of FIG. 3 including a discontinuity 43 in neutral return line 42. Discontinuity 43 may give rise to a change in source impedance Z_{S} although the change may not be significant. The local current I_{A} now flows via earth impedance Z_{E} causing voltage V₂ to rise above the neutral line voltage such that

V₂=V_{O}[Z_{E}/(Z_{E}+Z_{N}+Z_{L}+Z_{S})]

This causes a drop in voltage V₁ across the local network such that

$$\begin{matrix}{V}_{1} = {V}_{O} - {V}_{2} \\ = {V}_{O} - {V}_{O} [ {Z}_{E} / ( {Z}_{E} + {Z}_{N} + {Z}_{L} + {Z}_{S} ) ] \\ = {V}_{O} [ ( {Z}_{N} + {Z}_{S} ) / ( {Z}_{E} + {Z}_{N} + {Z}_{L} + {Z}_{S} ) ]\end{matrix}$$

Therefore in the event of discontinuity 43 in the neutral return line 42, the voltage V₁ across the local network 40 is less than the line voltage V_{O} since (Z_{N}+Z_{S})/(Z_{E}+Z_{N}+Z_{L}+Z_{S}) is less than 1. This drop in local voltage V₁ may be detected by comparing V₁ to a reference or standard voltage to provide an indication of the discontinuity or an impedance irregularity in neutral return line 42.

FIG. 5 provides an example of line voltage variations that may be present in a typical electrical distribution network. The variations include variations in “nominal supply voltage” and voltage changes such as steps, sags, spikes, etc. due to normal network operations, including voltage drops due to loads imposed on a local or distribution network, overloading of transformers, switching, lightning strikes, re-closer operations, etc.

FIG. 6 shows a conceptual diagram of one form of apparatus for detecting a discontinuity or impedance irregularity in an electrical power distribution system. The apparatus includes switchable impedance block 60 for applying an impedance to a line voltage supply. Impedance block 60 includes means for controlled switching of impedance to a circuit associated with the line voltage supply.

The apparatus includes voltage conditioning and measurement block 61 including a means for conditioning the mains input voltage and means for converting the voltage input from an analog into a digital representation by using an analog to digital converter.

The apparatus includes microprocessor and memory block 62 for controlling impedance block 60 and voltage conditioning and measurement block 61 and for determining and/or confirming whether the line voltage supply has a discontinuity or irregularity in a neutral line or wire.

The apparatus includes an audible and/or visual signal or alarm 63 to communicate to a consumer and/or a third party that a neutral return line or wire may contain a discontinuity or irregularity.

FIG. 7 shows a block diagram of one form of apparatus for detecting a fault in a neutral return line. The apparatus includes a switchable impedance module 70 including a relay controlled resistor and a voltage conditioning/measurement module 71 including one or more of an isolation transformer, one or more filters, a full wave rectifier and a voltage scaler. The apparatus includes analog to digital converter module 72 including an ADC converter for outputting average interval voltages. The voltages are output to memory data array module 73. Memory array module 73 stores at least 300 voltage entries in an array with each subsequent voltage measurement moving previously stored measurements one step in the array. The voltage measurements in memory array module 73 are passed to microcontroller module 74 as required. Microcontroller module 74 includes algorithms for conducting passive and active voltage tests as described below. Microcontroller module 74 interfaces latched audible and visual alarm module 75.

FIG. 8 shows a flow diagram of steps for conducting voltage tests including steps 80-90. Step 81 includes a start-up/self check sub-process and is illustrated further in FIG. 9 (refer steps 81a to 81e). Steps 83 and 89 include an active algorithm sub-process illustrated further in FIG. 10. Step 86 includes a passive algorithm sub-process illustrated further in FIG. 11.

Referring to FIG. 10 an active algorithm for detecting a broken neutral may include the following steps:
1. Measure line voltage and average over a first defined interval, i.e. V₁ over T₁ (step 83a).
2. Switch a known impedance in circuit (step 83b), and measure line voltage and average over a second defined interval while the known impedance is in circuit, i.e. V₂ over T₂ (step 83c).
3. Switch the known impedance out of circuit (step 83d), and measure line voltage and average over a third defined interval, i.e. V₃ over T₃ (step 83e).
4. Determine average step voltage resulting from having known impedance switched into circuit, i.e. V₂−((V₁+V₃)/2) (step 83f).
5. Dynamically adjust step voltage reference standard,
   ie. V_{ref}=V_{ref}*((V₁+V₃)/2)/230
   If the step voltage calculated is greater than the adjusted reference step voltage expected when the neutral return line is unbroken, the neutral return line is either broken or is unbroken but has unacceptably high impedance (step 83g).
6. As normally occurring voltage sags and spikes can result in step voltages that either hide a broken neutral condition, or create a step voltage that may mimic a broken neutral condition even when a neutral is not broken, the single test may be repeated in a series of single tests, at least often enough and sufficiently far apart so that naturally occurring anomalous voltages do not result in either false positive or false negative results. If the average of a test series of single tests indicates a broken neutral condition, the test series may be repeated D number of times after a defined time period has elapsed. If X out of D number of test series indicates a broken neutral condition, then signal a broken neutral condition signal may be triggered and alarm latched until reset (steps 83h, 83i, 83j).
7. Active test may be undertaken upon device start-up or reset, and preferably at regularly occurring intervals thereafter (step 81—FIG. 8).
8. Active test may be undertaken upon trigger from Passive broken neutral monitoring routine(s) (step 89—FIG. 8).

Active test variables may include:

Voltage Measurement Interval T=variable with initial value of 1 seconds
Time between single tests T_{I}=variable with initial value of 10 seconds
Number of single tests N_{I}=variable with initial value of 6
Time between test series T_{S}=variable with initial value of 30 seconds
Number of test series N_{S}=variable with initial value of 3 (including initial test)
Number of positive test series N_{P}=variable with initial value of 3 (including to signal broken neutral initial test)
Time between routine Active T_{R}=variable with initial value for testing of Tests 5 minutes
Critical Step Change Voltage V_{C}=variable with initial value of −1.0 Volts

Referring to FIG. 11, a passive algorithm for detecting a broken neutral (test #1) may include the following steps:
1. Continuously measure line voltage and average over a defined interval, i.e. V₁ over T₁ (step 86a).
2. Store measured voltages (step 86a).
3. If averaged voltages over a defined interval are above or below a defined voltage, potential of a broken neutral has been detected (steps 86b, 86c).
4. Trigger Active test (step 86c).
5. If Active test signals a broken neutral, then latch alarm until reset (step 90—FIG. 8).
6. If Active test does not signal a broken neutral, wait a defined period and resume passive testing.

Passive test #1 variables may include:

Voltage Averaging Interval T_{A1}=variable with initial value of 5 seconds
Critical Passive Upper Voltage V_{U}=variable with initial value of 275 Volts (RMS)
Critical Passive Lower Voltage VL=variable with initial value of 200 Volts (RMS)
Time between Failed Active and T_{R}=variable with initial value of 2 resumption of Passive Tests minutes

A passive algorithm for detecting a broken neutral (test #2) may include the following steps:
1. Continuously measure line voltage and average over a defined interval, i.e. V₁ over T₁ (step 86a).
2. Store measured voltages (step 86a).
3. If averaged voltages over a defined interval are below the previous defined interval by a defined voltage, a step change potentially resulting from a broken neutral has been detected (steps 86b, 86c).
4. Trigger Active test (step 86c).
5. If Active test signals a broken neutral, then latch alarm until reset (step 90—FIG. 8).
6. If Active test does not signal a broken neutral, wait a defined period and resume passive testing.

Passive test #2 variables may include:

Voltage Averaging Interval T_{A2}=variable with initial value of 20 seconds
Critical Passive Step Voltage V_{P}=variable with initial value of −20 Volts
Time between Failed Active T_{R}=variable with initial value of 2 minutes and resumption of Passive Tests

FIGS. 12a and 12b show a schematic diagram of one form of apparatus for detecting a fault in a neutral return line. The apparatus includes a power supply 120, which provides power for operation of microprocessor 121, alarm lights 122 and audible alarm 123. Microprocessor 121 may include a device type MSP430F133 manufactured by Texas Instruments. The apparatus includes switchable impedance 124 consisting of power resistors R10, R11, R26, and R27 switched by means of triac T1 under control of microprocessor 121. Switchable impedance 124 may have a value of substantially 220 ohms. Microprocessor 121 includes a software implementation of an algorithm as described below. Microprocessor 121 measures line voltage by means of an inbuilt analog to digital converter, controls operation of switchable impedance 124 via triac T1, and controls operation of alarm lights 122 and audible alarm 123 as required.

FIGS. 13 to 18 show flow diagrams of the associated device algorithm for detecting a discontinuity or impedance irregularity in a neutral return line or wire or earth return path.

FIG. 13 shows an algorithm for main system control including hardware initialization routines 130, software initialization routines 131 and main loop functions 132. Main loop functions 132 include an 8 mS non-critical periodic functions algorithm 133 performed every 8 mS and illustrated in FIG. 14a, a 250 mS non-critical periodic functions algorithm 134 performed at each 250 mS interval and illustrated in FIG. 14b, and a 1 second non-critical periodic functions algorithm 135 illustrated in FIGS. 15a and 15b.

Referring to FIG. 14a, the 8 mS non-critical functions algorithm 133 performs detailed control of triac T1 (refer FIG. 12b) during an active test. Called for every 8 mS, it performs a voltage measurement with the triac off for 100 mS and then another with the triac on for 100 mS followed by another with the triac off again for 100 mS. The on voltages are all added together to produce an average as are the off voltages. Each measurement starts at a mains zero crossing.

Referring to FIG. 14b, the 250 mS non-critical functions algorithm 134 starts A/D to samples at each 250 mS interval as well as timing the length of triac gate pulses.

Referring to FIGS. 15a and 15b the 1 second non-critical functions algorithm 135 includes a self test state that checks whether the user interface is OK. If it is OK it remains in the self test state for a short time displaying the start up code and then enters a passive test state initiating a measurement to start the process. The passive test state checks the voltage every second. If the voltage is out of spec or an active test was not performed for one hour the algorithm then starts an active test. If the user interface test fails the algorithm enters an error state.

The active test state controls the number of triac conduction pulses and processes the results of the test. There are 15 conduction pulses each 100 mS long and spaced 1 second apart. When the last pulse is done a voltage drop is calculated. If the voltage drop is in excess denoting a failed test another test is performed after 30 seconds. If the result of the active test is OK the algorithm waits in this state for 1 minute before reverting to the passive test state or a self test state. If the active test fails the algorithm enters an error state. If there is an over voltage or under voltage condition, the algorithm holds this state for 1 hour before performing the active test again.

Under normal operation, the apparatus may operate in a state of passive monitoring as shown in FIG. 15a. The apparatus may continuously measure line voltage, and check for one or more voltage changes that may indicate a discontinuity or impedance irregularity in a neutral return line or wire or earth return path.

The voltage changes may include line voltage dropping below 200 Volts, which may indicate high return path impedance, line voltage rising above 275 Volts, which may indicate a high return impedance at or near the supply transformer, or a 20 Volt step change drop in line voltage occurring over sequential 5 second intervals, that may be a result of an increase in consumer load and/or a change in impedance of the return path.

As shown in FIG. 5, naturally occurring voltage spikes and sags may mimic these and other passive voltage indicators of a discontinuity or impedance irregularity in a neutral return line or wire or earth return path.

For this reason should the apparatus detect one or more passive indicators, the apparatus may initiate an active test to confirm or deny a condition of discontinuity or impedance irregularity in a neutral return line or wire or earth return path.

The active test may include measuring line voltage before and after switching of a know impedance and a comparison of the difference in voltages, i.e. the voltage drop, with a reference standard.

Measurement of line voltage and switching of a known impedance may be undertaken as illustrated in FIGS. 15a and 15b, in a manner that minimises impact of naturally occurring voltage spikes and sags by means of averaging results of a multiple number of tests conducted over an interval, and then comparing the averaged result with a selected reference standard.

The algorithm shown in FIG. 18 is performed following completion of an analog to digital conversion. 400 samples are taken at 250 mS intervals giving a total of 100 mS or 10 cycles. Each value is added to a summing register to provide an effective average of the voltage.

Should the apparatus not confirm by means of active testing the presence of a discontinuity or impedance irregularity in a neutral return line or wire or earth return path, the apparatus returns to a state of passive monitoring.

Should the apparatus confirm by means of active testing the presence of a discontinuity or impedance irregularity in a neutral return line or wire or earth return path, the apparatus triggers appropriate alarm functions.

Finally, it is to be understood that various alterations, modifications and/or additions may be introduced into the constructions and arrangement of parts including algorithms previously described without departing from the spirit or ambit of the invention.

1. Apparatus for detecting a discontinuity or irregularity in a neutral return line of an electrical power distribution network including said neutral return line, an active line and an earth return, said apparatus including:
means for measuring a voltage change associated with a deliberate switching of a known impedance in said electrical network wherein said voltage change is due to a discontinuity or impedance irregularity in said neutral return line;
means for implementing an algorithm for identifying said discontinuity or impedance irregularity in presence of allowable variations in nominal supply voltage to said electrical network including voltage changes resulting from network operations that mimic or hide a discontinuity or impedance irregularity in said neutral return line; and
means for comparing a result of said measuring with a reference to provide an indication of said discontinuity or impedance irregularity.

2. Apparatus according to claim 1 wherein said algorithm is implemented to discriminate a network that includes said neutral return line from a network that does not include said neutral return line in presence of anomalies in said supply voltage.

3. Apparatus according to claim 1 wherein said reference is selected to discriminate a network that includes said neutral return line from a network that does not include said neutral return line.

4. Apparatus according to claim 1 wherein said reference includes data samples obtained from a plurality of sites when said network does not include said neutral return line.

5. Apparatus according to claim 1 wherein said reference includes data samples obtained from a plurality of sites when said network does include said neutral return line.

6. Apparatus according to claim 1 including means for measuring said voltage change in said network including voltage change that results from random or natural switching of impedances in said network.

7. Apparatus according to claim 1 including means for measuring said voltage change in said network including voltage change that results from said deliberate switching of a known impedance in said network.

8. Apparatus according to claim 1 wherein said means for measuring includes an analog to digital converter.

9. Apparatus according to claim 1 wherein said means for comparing includes a microprocessor and a memory for storing data associated with said reference.

10. Apparatus according to claim 1 wherein said indication includes an audible and/or visual alarm and/or an electrical signal.

11. A method for detecting a discontinuity or irregularity in a neutral return line of an electrical power distribution network including said neutral return line, an active line and an earth return, said method including:
measuring a voltage change associated with a deliberate switching of a known impedance in said electrical network wherein said voltage change is due to a discontinuity or impedance irregularity in said neutral return line;
implementing an algorithm for identifying said discontinuity or impedance irregularity in presence of allowable variations in nominal supply voltage to said electrical network including voltage changes resulting from network operations that mimic or hide a discontinuity or impedance irregularity in said neutral return line; and
comparing a result of said measuring with a reference to provide an indication of said discontinuity or impedance irregularity.

12. A method according to claim wherein said algorithm is implemented to discriminate a network that includes said neutral return line from a network that does not include said neutral return line in presence of anomalies in said supply voltage.

13. A method according to claim 11 wherein said reference is selected to discriminate a network that includes said neutral return line from a network that does not include said neutral return line.

14. A method according to claim 11 wherein said reference includes data samples obtained from a plurality of sites when said network does not include said neutral return line.

15. A method according to claim 11 wherein said reference includes data samples obtained from a plurality of sites when said network does include said neutral return line.

16. A method according to claim 11 including measuring said voltage change in said network including voltage change resulting from random or natural switching of impedances in said network.

17. A method according to claim 11 including measuring said voltage change in said network including voltage change resulting from said deliberate switching of a known impedance in said network.

18. A method according to claim 11 wherein said measuring is performed by means including an analog to digital converter.

19. A method according to claim 11 wherein said comparing is performed by means including a microprocessor and a memory for storing data associated with said reference.

20. A method according to claim 11 wherein said indication includes an audible and/or visual alarm and/or an electrical signal.

21. (canceled)

22. (canceled)
